(19) United States
(12) Patent Application Publication
(10) Pub. No.: US 2013/0119553 A1
(43) Pub. Date: May 16, 2013

(54) SEMICONDUCTOR PACKAGE AND METHOD OF MANUFACTURING THE SAME

(71) Applicants: Tae Sung JEONG, Gyeonggi-do (KR); Jung Soo BYUN, Gyeonggi-do (KR); Yul Kyo CHUNG, Gyeonggi-do (KR); Doo Hwan LEE, Gyeonggi-do (KR)

(72) Inventors: Tae Sung JEONG, Gyeonggi-do (KR); Jung Soo BYUN, Gyeonggi-do (KR); Yul Kyo CHUNG, Gyeonggi-do (KR); Doo Hwan LEE, Gyeonggi-do (KR)

(73) Assignee: SAMSUNG Electro-Mechanics Co., Ltd.

(21) Appl. No.: 13/438,483

(22) Filed: Apr. 3, 2012

(30) Foreign Application Priority Data
Nov. 10, 2011 (KR) 10-2011-0117018

(51) Int. Cl. H01L 23/498; H01L 21/78

(52) U.S. Cl. 257/774; 438/113; 257/E23.067; 257/E21.599

(57) ABSTRACT

Disclosed herein is a semiconductor package including an electrical device having a first lateral surface; and a core substrate including a cavity in which the electrical device is positioned, wherein the core substrate is inclined in a thickness direction of the core substrate and has a second lateral surface that defines the cavity.

### CROSS REFERENCE(S) TO RELATED APPLICATIONS

This application claims the benefit under 35 U.S.C. Section 119 of Korean Patent Application Serial No. 10-2011-0117018, entitled “Semiconductor Package and Method of Manufacturing the Same” filed on Nov. 10, 2011, which is hereby incorporated by reference in its entirety into this application.

### BACKGROUND OF THE INVENTION

1. Technical Field

The present invention relates to a semiconductor package and a method of manufacturing the same, and more particularly, to a semiconductor package for increasing production efficiency and a method of manufacturing the same.

2. Description of the Related Art

Semiconductor package technologies are used to protect manufactured semiconductor integrated circuit (IC) chips from external environments and to install the semiconductor IC chips in external electronic devices. In general, a semiconductor package includes at least one circuit board and an IC chip disposed on the circuit board. From among such circuit boards, an embedded printed circuit board (PCB) has a structure in which an electrical device is embedded in a core substrate in order to increase the integration degree of a semiconductor package.

Such a core substrate is manufactured by preparing electrical devices such as active devices and passive devices, positioning the electrical devices in a cavity of the core substrate, filling the remaining space of the cavity with a predetermined insulating material, and then electrically connecting an electrode terminal of the electrical device and a circuit pattern of the core substrate.

However, when the electrical device is positioned in the cavity of the core substrate, various materials and various processes are further required in order to temporally fix the electrical device to the cavity, thereby increasing manufacturing costs and reducing production efficiency. For example, an operation of preparing an adhesive material (e.g., an adhesive film) for fixing the electrical device to the cavity, an operation of fixing the electrical device to the cavity by using the adhesive material, an operation of removing the adhesive material, and the like are further performed.

### RELATED ART DOCUMENT

### Patent Document

(Patent Document 1) Korean Patent Laid-Open Publication No. 10-2006-0070767

### SUMMARY OF THE INVENTION

An object of the present invention is to provide a semiconductor package having a structure in which an electrical device is efficiently installed in a cavity of a core substrate.

Another object of the present invention is to provide a semiconductor package having a structure with increased heat dissipation efficiency of an electrical device.

Another object of the present invention is to provide a method of manufacturing a semiconductor package, having increased production efficiency.

Another object of the present invention is to provide a method of manufacturing a semiconductor package in which an electrical device is efficiently installed in a cavity of a core substrate.

Another object of the present invention is to provide a method of manufacturing a semiconductor package having increased heat dissipation efficiency of an electrical device.

According to an exemplary embodiment of the present invention, there is provided a semiconductor package including an electrical device having a first lateral surface; and a core substrate including a cavity in which the electrical device is positioned, wherein the core substrate is inclined in a thickness direction of the core substrate and has a second lateral surface that defines the cavity.

The electrical device may be inserted into the cativity through an open upper portion thereof and be positioned in the cavity, and the cavity may have a shape that is tapered toward a direction in which the electrical device is inserted.

The first lateral surface may have a shape corresponding to the second lateral surface.

The core substrate may further include a support that protrudes from the second lateral surface toward a center of the cavity and supports the electrical device.

The cavity may be a hole passing through the core substrate.

The cavity may have a trench structure formed by excavating the core substrate to a predetermined depth from one surface of the core substrate.

The second lateral surface and the first lateral surface may each be used as a stopper for fixing the electrical device in a predetermined portion of the cavity when the electrical device is inserted into the cavity.

The core substrate may be formed of a metal material.

The semiconductor package may further include an insulating layer covering the electrical device and the core substrate; and a metal circuit structure that is electrically connected to the electrical device on the insulating layer.

An inclination angle of the second lateral surface may range from 70° to 90° with respect to a line that traverses the core substrate in the thickness direction of the core substrate.

According to another exemplary embodiment of the present invention, there is provided a method of manufacturing a semiconductor package, the method including preparing an electrical device having a first lateral surface; preparing a core substrate including a cavity in which the electrical device is positioned; and positioning the electrical device in a predetermined portion of the cavity, wherein the preparing of the core substrate includes: preparing a base substrate; and forming a hole or a trench in the base substrate so as to form a second lateral surface that surrounds the first lateral surface and is inclined in a thickness direction of the base substrate.

The preparing of the electrical device may include preparing a substrate on which a plurality of integrated circuit (IC) chips are formed; and cutting the substrate so as to be inclined in a thickness direction of the substrate so that the first lateral surface has a shape corresponding to the second lateral surface.

The base substrate may be a metal substrate, and the core substrate may be used as a heat dissipating substrate of the electrical device.

The positioning of the electrical device in a predetermined portion of the cavity may be performed by using the second lateral surface and the first lateral surface as a stopper for fixing the electrical device in a predetermined portion of the cavity when the electrical device is inserted into the cavity.

The method may further include forming an insulating layer on the core substrate so as to cover the cavity; and forming a metal circuit structure that is electrically connected to the electrical device on the core substrate.

In the forming of the hole or the trench, an inclination angle of the second lateral surface may range from 70° to 90° with respect to a line that traverses the core substrate in the thickness direction of the core substrate.

### BRIEF DESCRIPTION OF THE DRAWINGS

FIG. 1 is a cross-sectional view of a semiconductor package according to an embodiment of the present invention;

FIG. 2 is a cross-sectional view of a core substrate of FIG. 1, according to an embodiment of the present invention

FIG. 3 is a cross-sectional view of a core substrate obtained by modifying the core substrate of FIGS. 1 and 2, according to another embodiment of the present invention;

FIG. 4 is a cross-sectional view of a core substrate obtained by modifying the core substrate of FIGS. 1 and 2, according to another embodiment of the present invention;

FIG. 5 is a flow chart of a method of manufacturing a semiconductor package, according to an embodiment of the present invention; and

FIGS. 6 through 10 are cross-sectional views for explaining a method of manufacturing a semiconductor package, according to an embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

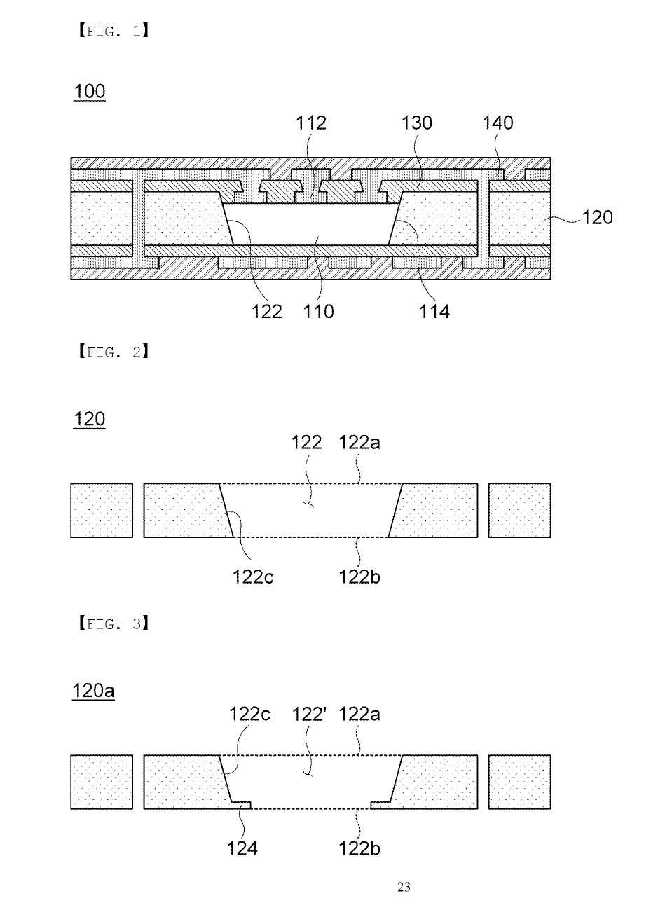

FIG. 1 is a cross-sectional view of a semiconductor package 100 according to an embodiment of the present invention. FIG. 2 is a cross-sectional view of a core substrate 120 of FIG. 1, according to an embodiment of the present invention.

Referring to FIGS. 1 and 2, the semiconductor package 100 may include an electrical device 110, the core substrate 120, an insulating layer 130, and a metal circuit structure 140.

The electrical device 110 may be positioned in a cavity 122. The electrical device 110 may include at least one of an active device and a passive device. An example of the electrical device 110 may include a semiconductor integrated circuit (IC) chip. The electrical device 110 may have a first surface on which an external connection terminal 112 is formed, a second surface opposite to the first surface, and a first lateral surface 114 connecting the first and second surfaces. In this case, the electrical device 110 may have a shape that is tapered from the first surface toward the second surface. Thus, the first lateral surface 114 may be inclined so as to be close to an inner part of the electrical device 110 from the first surface toward the second surface.

The core substrate 120 may be positioned in the semiconductor package 100 and may have a structure surrounding the first lateral surface 114 of the electrical device 110. The core substrate 120 may include the cavity 122 that provides a space in which the electrical device 110 is positioned. The cavity 122 may be a hole passing through the core substrate 120 and may be tapered in a thickness direction of the core substrate 120. In more detail, the cavity 122 may be defined by an open upper portion 122a, an open lower portion 122b, and a second lateral surface 122c of the core substrate 120, which connects the upper and lower surfaces 122a and 122b so as to surround the first lateral surface 114 of the electrical device 110. In this case, the second lateral surface 122c may have a shape corresponding to the first lateral surface 114 of the electrical device 110. Thus, the cavity 122 may be tapered from the upper portion 122a toward the lower portion 122b.

In this case, an inclination angle of each of the first and second lateral surfaces 114 and 122c may be adjusted so that the electrical device 110 may be accurately inserted into a predetermined portion inside the cavity 122. For example, the inclination angle of the second lateral surface 122c may range from 70° to 90° with respect to a line that traverses the core substrate 120 in the thickness direction. When the inclination angle of the second lateral surface 122c is smaller than 70° or greater than 90°, the electrical device 110 may be less accurately inserted into the inner portion inside the cavity 122 and it may not be easy to process the first and second lateral surfaces 114 and 122c.

In addition, a material of the core substrate 120 may be changed in various ways. An example of the core substrate 120 may include a resin-based insulating sheet. Another example of the core substrate 120 may include a metal sheet. When the core substrate 120 includes a metal sheet, the core substrate 120 may be used as a heat dissipation substrate for dissipating heat generated from the electrical device 110.

The insulating layer 130 may cover two surfaces of the core substrate 120. The insulating layer 130 may be formed by performing a lamination process using an insulator on the core substrate 120.

The metal circuit structure 140 may electrically connect the electrical device 110 and an external device (not shown). For example, the metal circuit structure 140 may include a conductive via formed in the core substrate 120, a conductive pattern that is connected to the conductive via on the insulating layer 130, and the like.

As described above, the semiconductor package 100 may include a structure in which the second lateral surface 122c of the core substrate 120, which surrounds the first lateral surface 114 of the electrical device 110, is inclined. In addition, the first lateral surface 114 of the electrical device 110 may have a structure corresponding to the second lateral surface 122c of the core substrate 120. In this case, while the electrical device 110 is inserted into the cavity 122 through the open upper portion 122a of the core substrate 120, the electrical device 110 may be fixed inside the cavity 122 of the core substrate 120 without using any separate adhesive material such as an adhesive film. Thus, a semiconductor package according to the present invention may have a structure in which an electrical device is fixed inside a cavity of a core substrate without using any separate adhesive material.

In the semiconductor package 100 according to the present embodiment, the first lateral surface 114 of the electrical device 110 may be correspondingly inclined to the second lateral surface 122c of the core substrate 120. Thus, in the semiconductor package according to the present invention, since a lateral surface of the electrical device has a shape corresponding to a lateral surface of the cavity of the core substrate, the electrical device may be stably installed inside the cavity.

In the semiconductor package 100 according to the present embodiment, the first lateral surface 114 of the electrical device 110 and the second lateral surface 122c of the core substrate 120, which surrounds the first lateral surface 114, may have shapes corresponding to each other, and the core substrate 120 may be formed of a metal material. Accordingly, in the semiconductor package according to the present invention, the core substrate surrounding the electrical device may be formed of a metal material, thereby increasing heat dissipation efficiency of the electrical device.

With reference to FIGS. 1 and 2, various modified examples of the core substrate 120 will now be described.

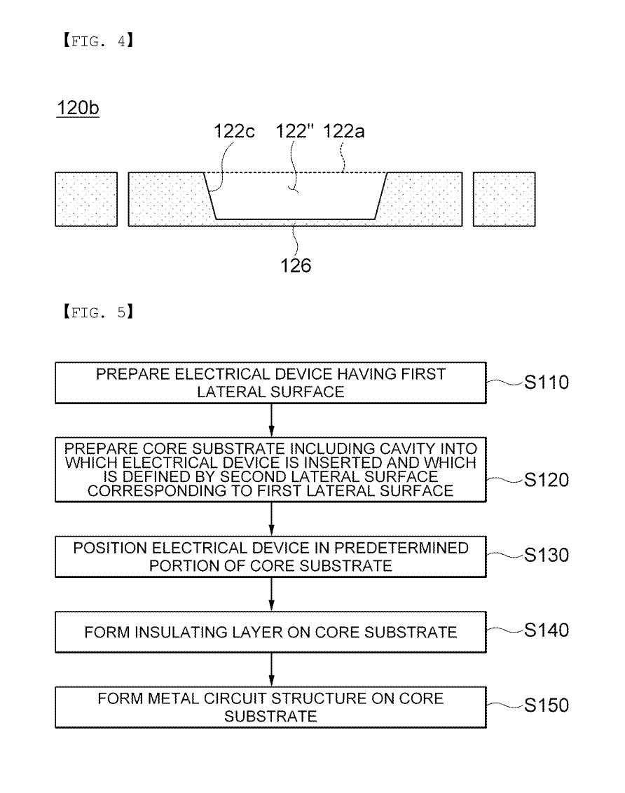

FIG. 3 is a cross-sectional view of a core substrate 120a obtained by modifying the core substrate 120 of FIGS. 1 and 2, according to another embodiment of the present invention. Referring to FIG. 3, the core substrate 120a according to the modified embodiment may include a cavity 122′ formed therethrough and may further include a support 124 that protrudes from a portion of the second lateral surface 122c, which is adjacent to the open lower portion 122b, toward the cavity 122′. When the electrical device 110 is inserted into and positioned in the cavity 122′, the support 124 may help the electrical device 110 to be supported and to be fixed to a predetermined portion.

FIG. 4 is a cross-sectional view of a core substrate 120b obtained by modifying the core substrate 120 of FIGS. 1 and 2, according to another embodiment of the present invention. Referring to FIG. 4, the core substrate 120b according to the modified embodiment may include a cavity 122″ having a trench structure formed by excavating the core substrate 120b to a predetermined depth from the upper portion 122a. In this case, the cavity 122″ may be defined by the open upper portion 122a, the second lateral surface 122c, and a closed lower portion 126. The closed lower portion 126 may help the electrical device 110 to be supported and to be fixed to a predetermined portion when the electrical device 110 is inserted into and positioned in the cavity 122″.

Hereinafter, a method of manufacturing a semiconductor package according to an embodiment of the present invention will be described in detail. In this case, a repeated explanation of the semiconductor package 100 described with reference to FIG. 1 will not be given or will be simplified.

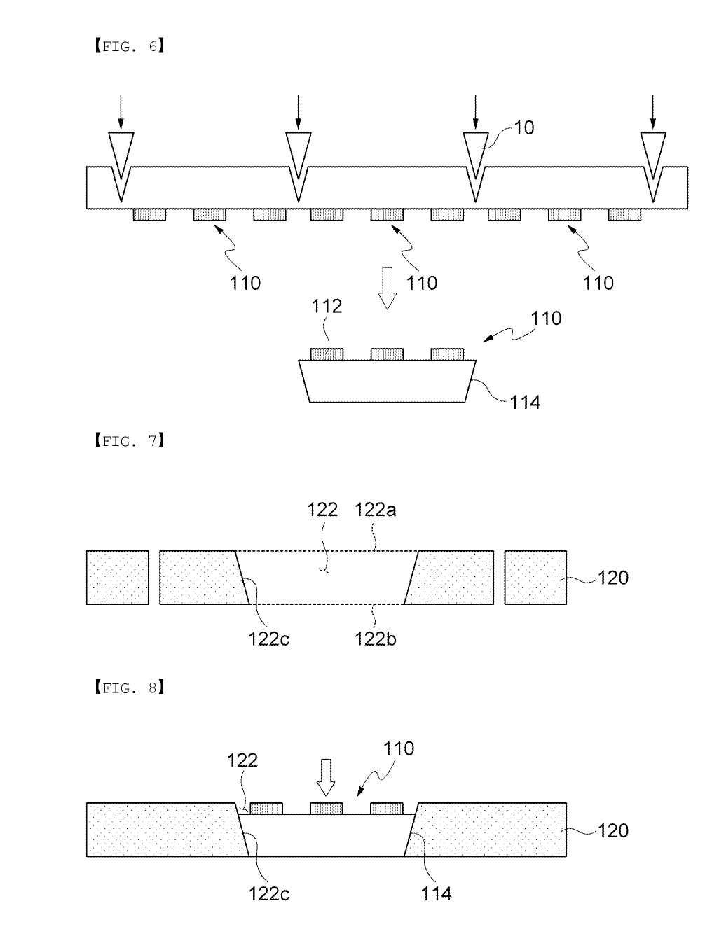

FIG. 5 is a flow chart of a method of manufacturing a semiconductor package, according to an embodiment of the present invention. FIGS. 6 through 10 are cross-sectional views for explaining a method of manufacturing a semiconductor package, according to an embodiment of the present invention.

Referring to FIGS. 5 and 6, the electrical device 110 having the first lateral surface 114 may be prepared (S110). For example, operation 5110 of preparing the electrical device 110 may include dividing a substrate on which a plurality of IC chips are formed into a plurality of individual IC chips by performing a dicing process using a predetermined cutting device 10 on the substrate. The external connection terminal 112 may be formed on the first surface of the electrical device 110. An example of the cutting device 10 may include a dicing blade.

In addition, during operation 5110 of preparing the electrical device 110, the first lateral surface 114 of the electrical device 110 may be formed to be inclined. For example, a cutting portion of the dicing blade has an inclination structure, and thus the first lateral surface 114 of the electrical device 110 may be formed to be inclined during a scribing process of the electrical device 110. To this end, the dicing blade may have a sectional view that is tapered toward an end thereof so as to have two inclined surfaces. Thus, during a cutting operation using the diving blade, the first lateral surface 114 of the electrical device 110 may be cut at an inclination angle by the two inclined surfaces of the dicing blade. In the above-described method, the electrical device 110 having the first lateral surface 114 that is inclined may be prepared simultaneously with the scribing process.

Alternatively, after the scribing process, the first lateral surface 114 of the electrical device 110 may be formed to be inclined by using a separate method of forming an inclined surface. Examples of the method of forming an inclined surface may include an etching process, a polishing process, or the like. The etching process may be a dry etching process or a wet etching process. In this case, after the scribing process, the first lateral surface 114 of the electrical device 110 may be formed to be inclined by performing a separate etching process on the first lateral surface 114. In addition, after the scribing process, the first lateral surface 114 of the electrical device 110 may be formed to be inclined by performing a mechanical polishing process on the first lateral surface 114.

Alternatively, the first lateral surface 114 of the electrical device 110 may be formed to be inclined by using a laser processing process. The scribing process itself may be performed using a laser on the first lateral surface 114 of the electrical device 110, or alternatively the laser processing process may be performed on the first lateral surface 114 after the scribing process, thereby forming the first lateral surface 114 of the electrical device 110 to be inclined.

Referring to FIGS. 5 and 7, the core substrate 120 including the cavity 122 into which the electrical device 110 is inserted and which is defined by the second lateral surface 122c corresponding to the first lateral surface 114 may be prepared (S120). In more detail, operation S120 of preparing the core substrate 120 may include preparing a base substrate and forming a hole through a predetermined portion of the base substrate, for installing a chip therein. In this case, the base substrate may be a plate formed of various materials. An example of the base substrate may include a resin-based insulating substrate. Another example of the base substrate may include a metal substrate. In this case, the core substrate 120 may be used as a heat dissipation substrate for dissipating heat generated from the electrical device 110.

In this case, in the forming of the hole, the cavity 122 may be inclined in a thickness direction of the base substrate so as to have a cylindrical shape that is tapered toward a predetermined direction. The predetermined direction may be a direction in which the electrical device 110 is inserted into the cavity 122. Thus, the cavity 122 defined by the open upper portion 122a, the open lower portion 122b, and the second lateral surface 122c connecting the upper and lower surfaces 122a and 122b may be formed in the core substrate 120.

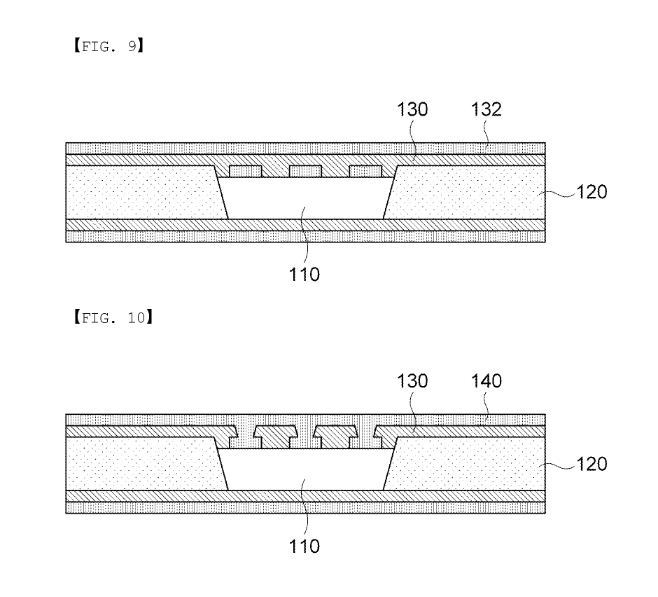

Referring to FIGS. 5 and 8, the electrical device 110 may be positioned in a predetermined portion of the cavity 122 of the core substrate 120 (S130). In more detail, the electrical device 110 and the core substrate 120 may be aligned so that the second surface of the electrical device 110 may face the cavity 122 and then the electrical device 110 may be inserted into the cavity 122. In this case, since the first lateral surface 114 and the second lateral surface 122c have corresponding shapes, the electrical device 110 may slide and may be inserted into the core substrate 120 and then may be stably stopped and may be fixed inside the cavity 122. To this end, an inclination angle of each of the first and second lateral surfaces 114 and 122c may be adjusted so that the electrical device 110 may be stopped inside the cavity 122 when being inserted into the cavity 122. Thus, when the electrical device 110 is inserted into the cavity 122, the first and second lateral surfaces 114 and 122c may each be used as a stopper for stopping the electrical device 110 in the cavity 122.

Referring to FIGS. 5 and 9, the insulating layer 130 may be formed on the core substrate 120 (S140). For example, operation 5140 of forming the insulating layer 130 may include preparing facing insulators shaped like a film on two surfaces of the core substrate 120 and pressuring the insulators onto the core substrate 120. An example of the insulator may include an insulating film formed of a predetermined insulating material. A portion of the insulators may be filled in a space of the cavity 122, which is not filled with the electrical device 110. Alternatively, operation 5140 of forming the insulating layer 130 may include forming a prepreg layer on the core substrate 120.

In operation 5140 of forming the insulating layer 130, a metal thin film 132 may be stacked on the insulating layer 130. For example, when the insulating layer 130 is a resin layer or a prepreg layer, operation S140 of forming the insulating layer 130 may further include stacking the metal thin film 132 on the resin layer or the prepreg layer. An example of the metal thin film 132 may include a copper (Cu) thin film formed of Cu. The Cu thin film 132 may be previously formed on the insulating layer 130 prior to forming the insulating layer 130 on the core substrate 120. In this case, a predetermined metal layer may be formed on the core substrate 120 by attaching the insulating layer 130 onto the core substrate 120 when the Cu thin film 132 is stacked on the insulating layer 130 having a film shape.

Referring to FIGS. 5 and 10, the metal circuit structure 140 may be formed on the core substrate 120 (S150). Operation 5150 of forming the metal circuit structure 140 may include forming a conductive via and a conductive pattern by selectively performing a plating process, a delaminating process, and an etching process, and the like on the core substrate 120.

As described above, in the method of manufacturing a semiconductor package according to the present embodiment, the first lateral surface 114 of the electrical device 110 is inclined and the second lateral surface 122c of the cavity 122 in which the electrical device 110 is positioned and which surrounds the first lateral surface 114 is inclined. Thus, electrical device 110 may be inserted into and fixed to a predetermined portion of the cavity 122 by using the first and second lateral surfaces 114 and 122c. Thus, when a method of manufacturing a semiconductor package according to the present invention is used, an electrical device is fixed inside a cavity of a core substrate without using any separate adhesive material, thereby increasing production efficiency of the semiconductor package.

In the method of manufacturing a semiconductor package according to the present embodiment, the first lateral surface 114 of the electrical device 110 and the second lateral surface 122c of the core substrate 120 may have shapes corresponding to each other, and thus the electrical device 110 may be stably inserted into the cavity 122. Thus, in the method of manufacturing a semiconductor package according to the present invention, a lateral surface of the electrical device has a shape corresponding to a lateral surface of the cavity of the core substrate, and thus the electrical device may be stably installed in the cavity.

The semiconductor package 100 according to the present embodiment, the first lateral surface 114 of the electrical device 110 and the second lateral surface 122c of the core substrate 120, which surrounds the first lateral surface 114, may have shapes corresponding to each other, and the core substrate 120 may include a metal material. In the method of manufacturing a semiconductor package according to the present invention, the core substrate surrounding the electrical device may be formed of a metal material, thereby increasing heat dissipation efficiency of the electrical device.

The semiconductor package according to the present invention may have a structure in which the electrical device is fixed inside the cavity of the core substrate without using any separate adhesive material.

In the semiconductor package according to the present invention, the core substrate surrounding the electrical device is formed of a metal material, thereby increasing heat dissipation efficiency of the electrical device.

In the semiconductor package according to the present invention, a lateral surface of the electrical device has a shape corresponding to a lateral surface of the cavity of the core substrate, and thus the electrical device may be stably installed in the cavity.

When the method of manufacturing a semiconductor package according to the present invention is used, the electrical device is fixed inside the cavity of the core substrate without using any separate adhesive material, thereby increasing production efficiency of the semiconductor package.

In the method of manufacturing a semiconductor package according to the present invention, the core substrate surrounding the electrical device may be formed of a metal material, thereby increasing heat dissipation efficiency of the electrical device.

In the method of manufacturing a semiconductor package according to the present invention, a lateral surface of the electrical device has a shape corresponding to a lateral surface of the cavity of the core substrate, and thus the electrical device may be stably installed in the cavity.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A semiconductor package, comprising:
an electrical device having a first lateral surface; and
a core substrate including a cavity in which the electrical device is positioned,
wherein the core substrate is inclined in a thickness direction of the core substrate and has a second lateral surface that defines the cavity.

2. The semiconductor package according to claim 1, wherein the electrical device is inserted into the cativity through an open upper portion thereof and is positioned in the cavity, and the cavity has a shape that is tapered toward a direction in which the electrical device is inserted.

3. The semiconductor package according to claim 1, wherein the first lateral surface has a shape corresponding to the second lateral surface.

4. The semiconductor package according to claim 1, wherein the core substrate further includes a support that protrudes from the second lateral surface toward a center of the cavity and supports the electrical device.

5. The semiconductor package according to claim 1, wherein the cavity is a hole passing through the core substrate.

6. The semiconductor package according to claim 1, wherein the cavity has a trench structure formed by excavating the core substrate to a predetermined depth from one surface of the core substrate.

7. The semiconductor package according to claim 1, wherein the second lateral surface and the first lateral surface are each used as a stopper for fixing the electrical device in the cavity when the electrical device is inserted into the cavity.

8. The semiconductor package according to claim 1, wherein the core substrate is formed of a metal material.

9. The semiconductor package according to claim 1, further comprising:
an insulating layer covering the electrical device and the core substrate; and
a metal circuit structure that is electrically connected to the electrical device on the insulating layer.

10. The semiconductor package according to claim 1, wherein an inclination angle of the second lateral surface ranges from 70° to 90° with respect to a line that traverses the core substrate in the thickness direction of the core substrate.

11. A method of manufacturing a semiconductor package, the method comprising:
preparing an electrical device having a first lateral surface;
preparing a core substrate including a cavity in which the electrical device is positioned; and
positioning the electrical device in the cavity,
wherein the preparing of the core substrate includes:
preparing a base substrate; and
forming a hole or a trench in the base substrate so as to form a second lateral surface that surrounds the first lateral surface and is inclined in a thickness direction of the base substrate.

12. The method according to claim 11, wherein the preparing of the electrical device includes:
preparing a substrate on which a plurality of integrated circuit (IC) chips are formed; and
cutting the substrate so as to be inclined in a thickness direction of the substrate so that the first lateral surface has a shape corresponding to the second lateral surface.

13. The method according to claim 12, wherein the cutting of the substrate is performed by cutting the substrate to be inclined by using a dicing blade having two inclined surfaces for cutting the substrate.

14. The method according to claim 11, wherein the base substrate is a metal substrate, and the core substrate is used as a heat dissipating substrate of the electrical device.

15. The method according to claim 11, wherein the positioning of the electrical device in the cavity is performed by using the second lateral surface and the first lateral surface as a stopper for fixing the electrical device in the cavity when the electrical device is inserted into the cavity.

16. The method according to claim 11, further comprising:
forming an insulating layer on the core substrate so as to cover the cavity; and
forming a metal circuit structure that is electrically connected to the electrical device on the core substrate.

17. The method according to claim 11, wherein, in the forming of the hole or the trench, an inclination angle of the second lateral surface ranges from 70° to 90° with respect to a line that traverses the core substrate in the thickness direction of the core substrate.
